(19) United States
(12) Patent Application Publication
(10) Pub. No.: US 2020/0083288 A1
(43) Pub. Date: Mar. 12, 2020

(54) MAGNETIC MEMORY

(71) Applicant: TOSHIBA MEMORY CORPORATION, Tokyo (JP)

(72) Inventor: Hiroyuki KANAYA, Seoul (KR)

(73) Assignee: TOSHIBA MEMORY CORPORATION, Tokyo (JP)

(21) Appl. No.: 16/298,952

(22) Filed: Mar. 11, 2019

(30) Foreign Application Priority Data
Sep. 11, 2018 (JP) 2018-169546

(51) Int. Cl. H01L 27/22; H01L 43/10; H01L 43/08; G11C 11/16

(52) U.S. Cl. CPC H01L 27/228; H01L 43/10; H01L 43/08; G11C 11/161; G11C 11/1659; G11C 11/1675; G11C 11/1655; G11C 11/1657; G11C 11/1673

(57) ABSTRACT

According to one embodiment, a magnetic memory includes: a semiconductor substrate; a switching element above the semiconductor substrate, the switching element provided between a first terminal and a second terminal; a first contact portion coupled to the first terminal and provided in a first insulator layer on the semiconductor substrate; a second contact portion including copper and provided in a second insulator layer on the first insulator layer; a conductive layer provided on the second contact portion; and a magnetoresistive effect element provided on the conductive layer.

### CROSS-REFERENCE TO RELATED APPLICATIONS

This application is based upon and claims the benefit of priority from Japanese Patent Application No. 2018-169546, filed Sep. 11, 2018, the entire contents of which are incorporated herein by reference.

### FIELD

Embodiments described herein relate generally to a magnetic memory.

### BACKGROUND

Research and development on the structure and constituents of a memory cell including a magnetoresistive effect element have been promoted for improving the properties of a magnetic memory.

### BRIEF DESCRIPTION OF THE DRAWINGS

FIG. 1 is a diagram showing a configuration example of a magnetic memory of an embodiment.

FIG. 2 is a diagram showing a configuration example of a memory cell array of the magnetic memory.

FIG. 3 is a top view schematically showing a structure example of a magnetoresistive effect element of the magnetic memory.

FIG. 4 is a cross-sectional diagram schematically showing a structure example of the magnetoresistive effect element of the magnetic memory.

FIG. 5 is a cross-sectional diagram schematically showing a structure example of a memory cell of the magnetic memory of the embodiment.

FIGS. 6 to 17 are cross-sectional step diagrams respectively showing a step of a method of manufacturing the magnetic memory of the embodiment.

FIGS. 18 and 19 are diagrams showing modifications of the magnetic memory of the embodiment.

### DETAILED DESCRIPTION

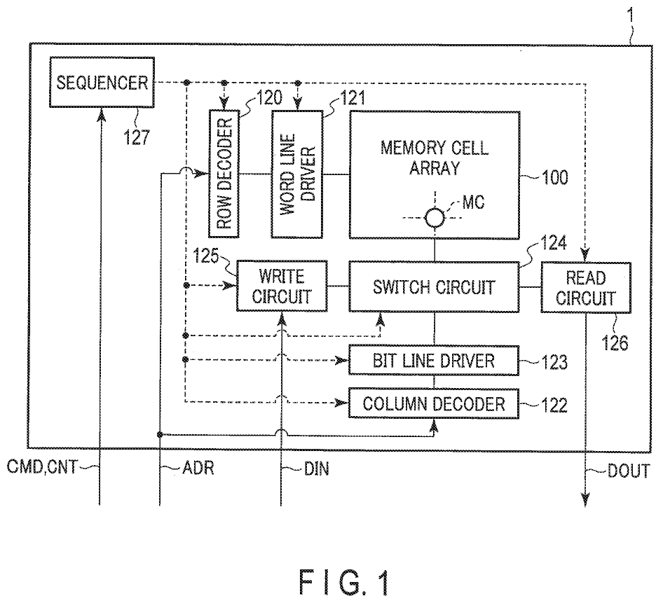

Hereinafter, the present embodiments will be described in detail with reference to the accompanying drawings (FIGS. 1 to 19). In the description below, elements having the same functions and configurations will be denoted by the same reference symbols. Also, in the embodiments described below, when elements are denoted by reference symbols (e.g., a word line WL, a bit line BL, various voltages and signals, and the like) with numbers or alphabetical characters for distinction at the end of the reference symbols but are not necessarily distinguished from each other, such numbers or alphabetical characters may be omitted in the description.

In general, according to one embodiment, a magnetic memory includes: a semiconductor substrate; a switching element above the semiconductor substrate, the switching element provided between a first terminal and a second terminal; a first contact portion coupled to the first terminal and provided in a first insulator layer on the semiconductor substrate; a second contact portion including copper and provided in a second insulator layer on the first insulator layer; a conductive layer provided on the second contact portion; and a magnetoresistive effect element provided on the conductive layer.

### (1) EMBODIMENT

A magnetic memory of an embodiment and a method of manufacturing the same will be described with reference to FIGS. 1 to 17.

### (a) Configuration Example

A configuration example of the magnetic memory of the embodiment will be described with reference to FIGS. 1 to 5.

FIG. 1 is a block diagram illustrating the configuration example of the magnetic memory of the present embodiment.

In FIG. 1, a memory device 1 of the present embodiment is electrically coupled to an external device (not illustrated in the drawings), such as a controller, processor, or host device, etc.

The magnetic memory (memory device) 1 receives a command CMD, an address ADR, input data DIN, and various control signals CNT from the external device. The magnetic memory 1 transmits output data DOUT to the external device.

As shown in FIG. 1, the magnetic memory 1 includes at least a memory cell array 100, a row decoder 120, a word line driver (row line control circuit) 121, a column decoder 122, a bit line driver (column line control circuit) 123, a switch circuit 124, a write circuit (write control circuit) 125, a read circuit (read control circuit) 126, and a sequencer 127.

The memory cell array 100 includes a plurality of memory cells MC.

The row decoder 120 decodes a row address included in the address ADR. The word line driver 121 selects a row (e.g., word line) of the memory cell array 100 based on a result of decoding the row address. The word line driver 121 can supply a predetermined voltage to the word line.

The column decoder 122 decodes a column address included in the address ADR.

The bit line driver 123 selects a column (e.g., bit line) of the memory cell array 100 based on a result of decoding the column address. The bit line driver 123 is coupled to the memory cell array 100 via the switch circuit 124. The bit line driver 123 can supply a predetermined voltage to the bit line.

The switch circuit 124 couples one of the write circuit 125 and the read circuit 126 to the memory cell array 100 and the bit line driver 123. Thereby, an MRAM 1 executes an operation corresponding to a command.

In a write operation, the write circuit 125 supplies a memory cell (selected cell) selected based on the address ADR with various voltages and/or currents for writing data. For example, the data DIN is supplied to the write circuit 125 as data to be written to the memory cell array 100. Thereby, the write circuit 125 writes the data DIN in the memory cell MC. The write circuit 125 includes, for example, a write driver/sinker.

In a read operation, the read circuit 126 supplies the selected cell, based on the address ADR, with various voltages and/or currents for reading data. Thereby, the data stored in the memory cell MC is read.

The read circuit 126 outputs, to the outside of the magnetic memory 1, data read from the memory cell array 100 as the output data DOUT.

The read circuit 126 includes, for example, a read driver and a sense amplifier circuit.

The sequencer 127 receives a command CMD and various control signals CNT. The sequencer 127 controls an operation of each of the circuits 120 to 126 in the magnetic memory 1 based on the command CMD and the control signals CNT. The sequencer 127 can transmit the control signals CNT to the external device according to an operation state in the magnetic memory 1.

For example, the sequencer 127 holds various information related to the write operation and the read operation as setting information.

The various signals CMD, CNT, ADR, DIN, and DOUT may be supplied to a predetermined circuit in the magnetic memory 1 via an interface circuit provided separately from a chip (package) of the magnetic memory 1, or may be supplied to the respective circuits 120 to 127 from an input-output circuit (not illustrated in the drawings) in the magnetic memory 1.

In the magnetic memory (e.g., MRAM) 1 of the present embodiment, the magnetoresistive effect element is used for a memory element in the memory cell MC.

### <Internal Configuration of Memory Cell Array>

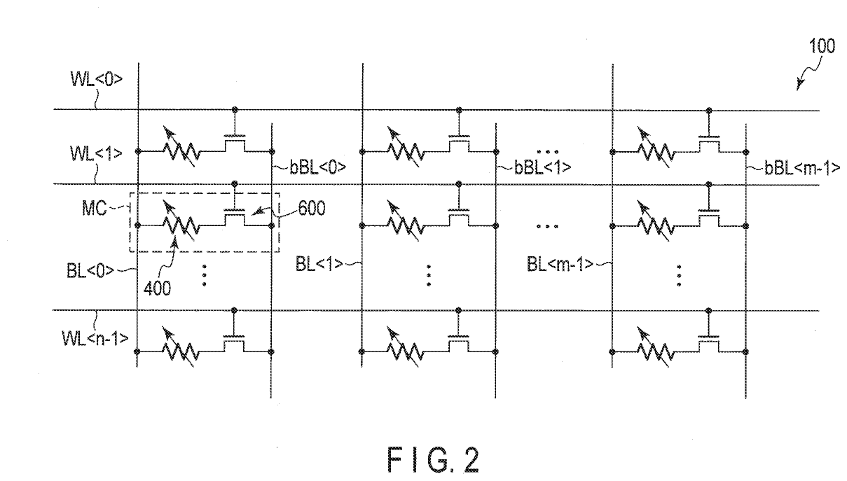

FIG. 2 is an equivalent circuit diagram showing an example of an internal configuration of the memory cell array of the MRAM according to the present embodiment.

As illustrated in FIG. 2, multiple (n) word lines WL (WL<0>, WL<1>, . . . WL<n−1>) are provided in the memory cell array 100. Multiple (m) bit lines BL (BL<O>, BL<1>, . . . , BL<m−1>) and multiple (m) bit lines bBL (bBL<0>, bBL<1>, . . . , bBL<m−1>) are provided in the memory cell array 100. One bit line BL and one bit line bBL form a bit line pair. In the description below, the bit line bBL may be referred to as a source line for the sake of clarity of the description.

The memory cells MC are arranged in a matrix in the memory cell array 100.

The memory cells MC aligned in a row direction (word line direction) are coupled to a common word line WL. The word lines WL are coupled to the word line driver 121. The word line driver 121 controls the potential of the word lines WL based on the row address. Thereby, a word line WL (row) indicated by the row address is selected and activated.

The memory cells MC aligned in a column direction (bit line direction) are coupled in common to two bit lines BL and bBL that belong to a bit line pair. The bit lines BL and bBL are coupled to the bit line driver 123 via the switch circuit 124.

The switch circuit 124 couples the bit lines BL and bBL corresponding to the column address to the bit line driver 123. The bit line driver 123 controls the potential of the bit lines BL and bBL. Thereby, bit lines BL and bBL (column) indicated by the column address are selected and activated.

Also, the switch circuit 124 couples the selected bit lines BL and bBL to the write circuit 125 or the read circuit 126 according to an operation required of the memory cell MC.

The memory cell array 100 may have a structure of a hierarchical bit line form. In this case, a plurality of global bit lines are provided in the memory cell array 100. Each bit line BL is coupled to one global bit line via a corresponding switching element. Each source line bBL is coupled to another global bit line via a corresponding switching element. The global bit lines are coupled to the write circuit 125 and the read circuit 126 via the switch circuit 124. By the switching element corresponding to the address being set to an ON state, the selected cell is coupled to the global bit line via the ON-state switching element.

For example, the memory cell MC includes one magnetoresistive effect element 400 and one cell transistor 600. The cell transistor 600 is a field-effect transistor (e.g., a MOS transistor).

One end of the magnetoresistive effect element 400 is coupled to the bit line BL. The other end of the magnetoresistive effect element 400 is coupled to one end (one of a source/drain) of the cell transistor 600. The other end (the other of the source/drain) of the cell transistor 600 is coupled to the bit line bBL. The word line WL is coupled to a gate of the cell transistor 600.

The memory cell MC may include two or more magnetoresistive effect elements 400 and may include two or more cell transistors 600.

The magnetoresistive effect element 400 functions as a memory element. The cell transistor 600 functions as a selection element of the memory cell MC.

A resistance state (magnetization alignment) of the magnetoresistive effect element 400 changes when a voltage or current having a certain magnitude is supplied to the magnetoresistive effect element 400. Thereby, the magnetoresistive effect element 400 may take multiple resistance states (resistance values). Data of 1 or larger bits is associated with the multiple resistance states that the magnetoresistive effect element 400 may take. In this manner, the magnetoresistive effect element 400 is used as a memory element.

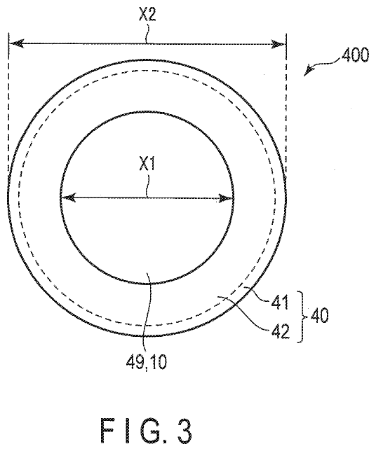

In the present embodiment, the configurations of the memory cell array and the memory cell are not limited to the examples illustrated in FIGS. 2 and 3.

### <Structure Example of Magnetoresistive Effect Element>

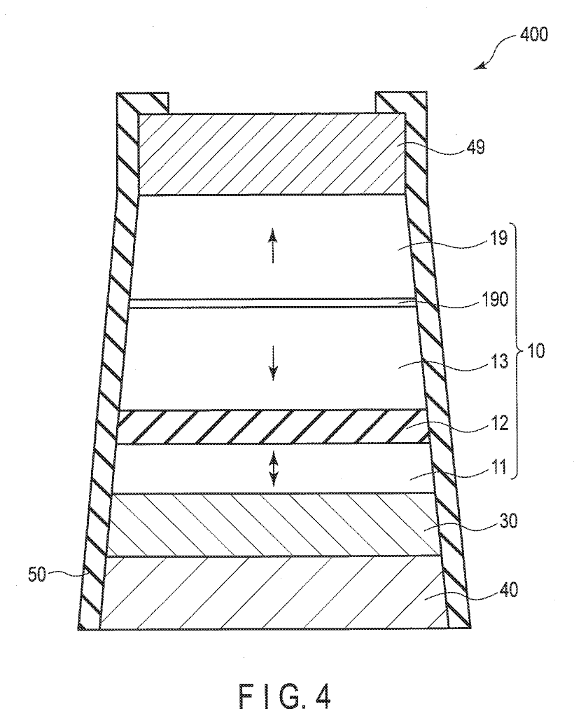

A structure example of a magnetoresistive effect element of the MRAM of the present embodiment will be described with reference to FIGS. 3 and 4.

FIG. 3 is a plan view schematically showing a structure example of the magnetoresistive effect element of the MRAM of the present embodiment. FIG. 4 is a cross-sectional diagram schematically showing a structure example of the magnetoresistive effect element of the MRAM of the present embodiment.

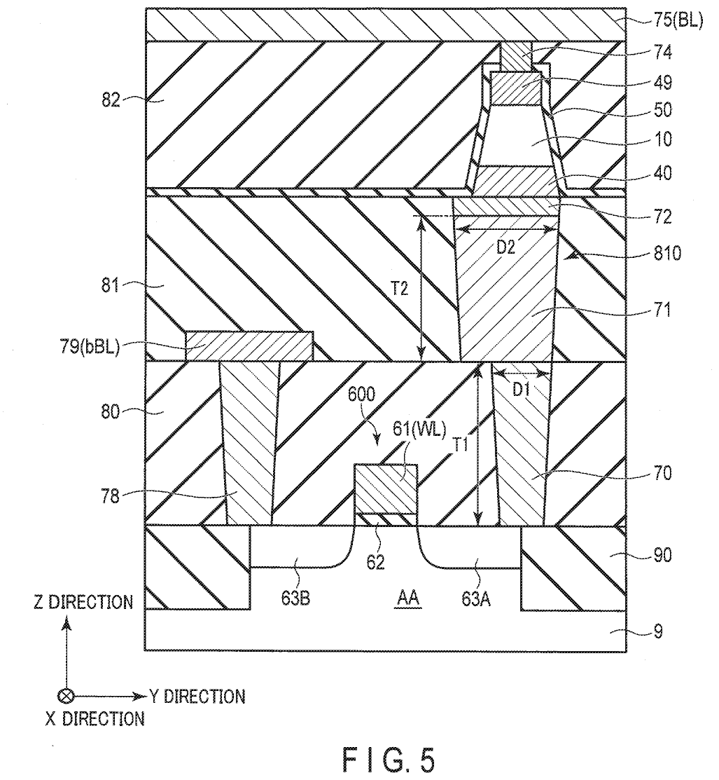

In the present embodiment, the magnetoresistive effect element 400 illustrated in FIGS. 4 and 5 has a truncated cone shape.

As illustrated in FIG. 3, the magnetoresistive effect element 400 of the present embodiment has a circular (or oval) planar shape. As illustrated in FIG. 4, the magnetoresistive effect element 400 of the present embodiment has a trapezoidal cross-section shape. The structure of the magnetoresistive effect element 400 is not limited to a truncated cone shape. For example, the planar shape of the magnetoresistive effect element 400 may be quadrilateral (e.g., square or rectangular). Also, in a magnetoresistive effect element having a quadrilateral planar shape, the corners of the quadrilateral may be rounded off or broken. The cross-section shape of the magnetoresistive effect element 400 may be quadrilateral. In the magnetoresistive effect element 400 having a quadrilateral cross-section shape, the corners of the quadrilateral may be rounded off or broken.

For example, a dimension X2 of a lower portion of the magnetoresistive effect element 400 (on a substrate side and an electrode 40 side), in a direction parallel to a surface of a substrate (semiconductor substrate) to be described later, is larger than a dimension X1 of an upper portion of the magnetoresistive effect element 400 (opposite to the substrate and on an electrode 49 side), in the direction parallel to the surface of the substrate.

The magnetoresistive effect element 400 includes a stack 10. The stack 10 includes at least two magnetic layers 11 and 13 and a non-magnetic layer 12. The stack 10 is provided between two electrodes 40 and 49. In the magnetoresistive effect element 400 of the present embodiment, the electrode 40 on the substrate side is referred to as a lower electrode 40, and the electrode 49 opposite to the substrate side is referred to as an upper electrode 49.

The magnetic layer 11, which is one of the two magnetic layers, is provided between the lower electrode 40 and the non-magnetic layer 12. The other magnetic layer 13 is provided between the non-magnetic layer 12 and the upper electrode 49. The non-magnetic layer 12 is provided between the two magnetic layers 11 and 13.

A magnetic tunnel junction is formed between the non-magnetic layer 12 and the magnetic layers 11 and 13. In the present embodiment, the magnetoresistive effect element having the magnetic tunnel junction is referred to as an MTJ element.

In the MTJ element 400, the non-magnetic layer 12 is referred to as a tunnel barrier layer 12. The tunnel barrier layer 12 is, for example, an insulator film.

The two magnetic layers 11 and 13 have magnetization. The one magnetic layer 11 is a magnetic layer having a variable direction of magnetization. The other magnetic layer 13 is a magnetic layer having an invariable direction of magnetization. In the description below, the magnetic layer 11 having a variable direction of magnetization is referred to as a storage layer 11, and the magnetic layer 13 having an invariable direction of magnetization is referred to as a reference layer 13. The storage layer 11 may also be referred to as a free layer or a free magnetization layer. The reference layer 13 may also be referred to as a pin layer, a pinned layer, a fixed magnetization layer, or an invariable magnetization layer.

A direction of magnetization of the magnetic layer 11 “being variable” means that a direction of magnetization of the magnetic layer 13 varies between before and after a current or voltage for switching a direction of magnetization of the storage layer 11 is supplied to the MTJ element 400. On the other hand, a direction of magnetization of the reference layer 13 “being invariable” or “being fixed” means that a direction of magnetization of the reference layer 13 does not vary between before and after a current or voltage for switching a direction of magnetization of the storage layer 11 is supplied to the MTJ element 400. A magnetization switching threshold value of the storage layer 11 and a magnetization switching threshold value of the reference layer 13 are controlled so that the direction of magnetization of the reference layer 13 is invariable. For example, in order to control the magnetization switching threshold values, a film thickness of the reference layer 13 is set to be larger than a film thickness of the storage layer 11 if the storage layer and the reference layer are the same material system.

The storage layer 11 and the reference layer 13 are, for example, magnetic layers having perpendicular magnetic anisotropy. The magnetization of the storage layer 11 and the magnetization of the reference layer 13 are approximately perpendicular to a layer face of the magnetic layers 11 and 13. A magnetization direction (magnetization easy axis direction) of the magnetic layers 11 and 13 is approximately parallel to the stacking direction of the two magnetic layers 11 and 13. The magnetization of the storage layer 11 is oriented toward the upper electrode side or the lower electrode side depending on the data to be stored. The fixed magnetization of the reference layer 13 is set (fixed) to be oriented toward either one of the upper electrode side or the lower electrode side.

The storage layer 11 includes, for example, cobalt iron boron (CoFeB) or iron boride (FeB). The tunnel barrier layer 12 is, for example, magnesium oxide or an insulating compound including magnesium oxide. The reference layer 13 includes, for example, cobalt iron boron (CoFeB) or iron boride (FeB). The reference layer 13 may also include cobalt platinum (CoPt), cobalt nickel (CoNi), or cobalt palladium (CoPd). The reference layer 13 is, for example, an alloy film or a multi-layer using these materials.

A shift canceling layer 19 is provided between the reference layer 13 and the upper electrode 49 in the stack 10. The shift canceling layer 19 is a magnetic layer for reducing a stray magnetic field of the reference layer 13. A direction of magnetization of the shift canceling layer 19 is opposite to the direction of magnetization of the reference layer 13. Thereby, a negative influence (e.g., magnetic field shift) on the magnetization of the storage layer 11 due to a stray magnetic field of the reference layer 13 is inhibited. For example, a material of the shift canceling layer 19 is the same as the material of the reference layer 13.

For example, the direction of magnetization of the reference layer 13 and the direction of magnetization of the shift canceling layer 19 are set to be opposite to each other by a SAF (synthetic antiferromagnetic) structure.

In the SAF structure, an intermediate layer 190 is provided between the reference layer 13 and the shift canceling layer 19. The intermediate layer 190 couples the reference layer 13 and the shift canceling layer 19 in an antiferromagnetic manner. The intermediate layer 190 is a non-magnetic metal film of ruthenium (Ru) or the like. A stack (SAF structure) that includes the magnetic layers 11 and 19 and the intermediate layer 190 may be referred to as a reference layer.

In the MTJ element 400 illustrated in FIG. 4, the storage layer 11 is located closer to the substrate side than the reference layer 13. The storage layer 11 is provided between the reference layer 13 and the substrate. For example, a dimension of the storage layer 11 in the direction parallel to the surface of the substrate is larger than a dimension of the reference layer 13 in the direction parallel to the surface of the substrate.

A resistance state (resistance value) of the MTJ element 400 varies in accordance with a relative relationship (magnetization alignment) between the direction of magnetization of the storage layer 11 and the direction of magnetization of the reference layer 13.

When the direction of magnetization of the storage layer 11 is the same as the direction of magnetization of the reference layer 13 (when the magnetization alignment of the MTJ element 400 is in a parallel alignment state), the MTJ element 400 has a first resistance value R1. When the direction of magnetization of the storage layer 11 is different from the direction of magnetization of the reference layer 13 (when the magnetization alignment of the MTJ element 400 is in an anti-parallel alignment state), the MTJ element 400 has a second resistance value R2 that is higher than the first resistance value R1.

In the present embodiment, the parallel alignment state of the MTJ element 400 is also indicated as a P state, and the anti-parallel alignment state of the MTJ element 400 is also indicated as an AP state.

For example, when the memory cell MC stores 1-bit data (“0” data or “1” data), first data (e.g., “0” data) is associated with the MTJ element 400 in a state of having the first resistance value R1 (first resistance state). Second data (e.g., “1” data) is associated with the MTJ element 400 in a state of having the second resistance value R2 (second resistance state).

The MTJ element 400 may be an in-plane magnetization-type MTJ element. In the in-plane magnetization-type MTJ element, the magnetization of the storage layer 11 and the reference layer 13 is oriented toward a direction perpendicular to the stacking direction of the magnetic layers 11 and 13. In the in-plane magnetization-type MTJ element, the magnetization easy axis direction of the storage layer and the reference layer is parallel to the layer face of the magnetic layers 11 and 13.

For example, a layer (hereinafter referred to as an underlying layer) 30 is provided between the lower electrode 40 and the magnetic layer 11. The underlying layer 30 is a layer capable of improving the properties of the magnetic layer 13 (e.g., magnetic properties and/or crystallinity of the magnetic layer), and/or the properties of the magnetic tunnel junction.

For example, the underlying layer 30 may be a single-layer film made of one material, or a multi-layer film made of different materials. The underlying layer 30 includes at least one of metal, boride, oxide, nitride, and the like. For example, a metal used in the underlying layer 30 is selected from aluminum (Al), beryllium (Be), magnesium (Mg), calcium (Ca), strontium (Sr), barium (Ba), scandium (Sc), yttrium (Y), lanthanum (La), silicon (Si), zirconium (Zr), hafnium (Hf), tungsten (W), chromium (Cr), molybdenum (Mo), niobium (Nb), titanium (Ti), tantalum (Ta), vanadium (V), and the like. A boride, oxide, and nitride of these metals, for example, are used in the underlying layer 30. Various compounds used in the underlying layer 30 may be binary compounds or ternary compounds.

The upper electrode 49 is provided above the magnetic tunnel junction 10. The upper electrode 49 is provided on the shift canceling layer 19. A material of the upper electrode 49 includes, for example, at least one of tungsten (W), tantalum (Ta), tantalum nitride (TaN), titanium (Ti), titanium nitride (TiN), and the like.

The lower electrode 40 is provided below the magnetic tunnel junction 10. The lower electrode 40 is provided on the bottom portion side of the underlying layer 30. A material of the lower electrode 40 includes, for example, at least one of tungsten, tantalum, tantalum nitride, titanium, titanium nitride, and the like.

Each of the electrodes 40 and 49 may be a single-layer structure or a multi-layer structure.

For example, an insulator film (hereinafter also referred to as a protective film, a sidewall film, or a sidewall insulator film) 50 covers a lateral face of the MTJ element 400. A material of the protective film 50 is selected from, for example, silicon nitride, aluminum nitride, aluminum oxide, and the like. The protective film 50 may be a single-layer film or a multi-layer film. An insulating compound including a material of the underlying layer 30 may be used as a material of the protective film 20. The protective film 50 need not be provided.

In the magnetoresistive effect element 400 of the magnetic memory of the present embodiment, the underlying layer between the storage layer 11 and the lower electrode 40 need not be provided. Also, in the present embodiment, the shift canceling layer 19 need not be provided between the upper electrode 49 and the reference layer 13.

### <Structure Example of Memory Cell>

FIG. 5 is a cross-sectional diagram showing a structure example of the memory cell of the MRAM according to the present embodiment.

As illustrated in FIG. 5, the memory cell MC is provided on a semiconductor substrate 9.

The cell transistor 600 is provided in an active area (semiconductor area) AA of the semiconductor substrate 9. The active area AA is a semiconductor area (semiconductor layer) partitioned by an insulator layer 90 in the semiconductor substrate 9.

The cell transistor 600 is a transistor of any type. For example, the cell transistor 600 is a field-effect transistor having a planar structure, a field-effect transistor having a three-dimensional structure, such as FinFET, or a field-effect transistor having a buried gate structure. In the description below, a cell transistor having a planar structure will be illustrated as an example.

In the cell transistor 600, a gate electrode 61 is provided above the active area AA via a gate insulator film 62. The gate electrode 61 extends in an X direction (or a gate width direction of the transistor). The gate electrode 61 functions as the word line WL.

In the cell transistor 600, two source/drain regions 63A and 63B are provided in the active area AA. The two source/drain regions 63A and 63B are aligned in a Y direction (a gate length direction of the transistor).

A contact plug 78 is provided on the source/drain region 63B. An interconnect (metal film) 79 as the source line bBL is provided on the contact plug 78.

Contact plugs 70 and 71 are provided on the source/drain region 63A. The contact plug 70 is provided in an interlayer insulator film 80. The contact plug 70 directly contacts the source/drain region 63A. For example, a part of a bottom face of the contact plug 70 directly contacts the insulator layer 90 in an element isolation region.

The contact plug 71 is provided in the interlayer insulator film 81. The contact plug 71 is provided on the contact plug 70. The contact plug 71 is stacked on an upper face of the contact plug 70.

A conductive layer 72 is provided between the MTJ element 400 and the contact plug 71.

The MTJ element 400 is provided above the contact plug 71 in a Z direction (the direction perpendicular to the surface of the substrate 9). The MTJ element 400 is provided in an interlayer insulator film 82. The MTJ element 400 vertically superposes on the contact plug 71 including Cu in the direction (Z direction) perpendicular to the surface of the substrate 9.

As described above, the MTJ element 400 includes two electrodes 40 and 49, and the stack 10 between the two electrodes 40 and 49. The stack 10 is a multi-layer film having a magnetic tunnel junction.

The electrode 40 is provided above the contact plug 71 via the conductive layer 72. The electrode 49 is provided above the electrode 40 via the stack 10. A contact plug (via plug) 74 is provided on the electrode 49. An interconnect (metal film) 75 as the bit line BL is provided on the contact plug 74 and the interlayer insulator film 82.

For example, the storage layer 11 of the MTJ element 400 of FIG. 4 is adjacent to the contact plug 71 including Cu via the conductive layer 72 (and the lower electrode 40) including Ta.

The protective film 50 is provided between the MTJ element 400 and the interlayer insulator film 82.

FIG. 5 is a simplified diagram of the structure of the magnetoresistive effect element. In FIG. 5, the stack (magnetic tunnel junction) 10 and the electrodes 40 and 49 are also illustrated in a simplified manner. Also, the shape of the protective film 50 illustrated in FIG. 5 can be adjusted as appropriate.

In the present embodiment, the two contact plugs (hereinafter referred to as a plug or a portion) 70 and 71 are provided between the MTJ element 400 and the cell transistor 600. The contact plug 71 is stacked on the contact plug 70 in the direction perpendicular to the surface of the substrate 9.

A material of the contact plug 70 is different from a material of the contact plug 71.

The contact plug 70 is, for example, a conductor including at least one of titanium nitride (TiN) and tungsten (W).

For example, a film thickness (a dimension in the direction perpendicular to the surface of the substrate 9) T1 of the contact plug 70 is thicker than a total value of a film thickness of the gate electrode 61 of the cell transistor 600 and a film thickness of the gate insulator film 62.

The contact plug 71 is a conductor (hereinafter referred to as a Cu-including layer) including copper (Cu). For example, the contact plug 71 is formed using a Cu layer, a Cu alloy layer, or a conductive Cu compound layer. If an alloy/compound including Cu is used for the contact plug 71, a ratio (composition ratio) of copper related to a plurality of elements included in the contact plug 71 is preferably a half or more of whole compositions of a plurality of elements forming the plug 71.

A film thickness (a dimension in the direction perpendicular to the surface of the substrate 9) T2 of the contact plug 71 has, for example, a dimension of 5 nm or more and 100 nm or less. The thickness (height) of the contact plug 71 can be adjusted as appropriate according to the dimension (e.g., a dimension in the direction perpendicular to the surface of the substrate 9) of the MTJ element 400. For example, the film thickness T2 of the contact plug 71 is the film thickness T1 of the contact plug 70 or less.

The contact plug 71 is formed in a self-aligning manner in the interlayer insulator film (insulator layer) 81 using a damascene method. The contact plug 71 is provided in a groove 810 in the interlayer insulator film 81. A cross-sectional shape (e.g., a shape of a cross section along a Y-Z direction) of the contact plug 71 is substantially the same as a cross-sectional shape of the groove 810.

A dimension (e.g., a dimension in the Y direction) D2 of the contact plug 71 in a direction parallel to the surface of the substrate 9 is substantially the same as a dimension of the groove 810 in the direction parallel to the surface of the substrate 9. The dimension D2 of the contact plug 71 is larger than a direction (e.g., a dimension X2) of the MTJ element 400 in the direction parallel to the surface of the substrate 9. In addition, the dimension D2 of the contact plug 71 is larger than the dimension D1 of the contact plug 70 in the direction parallel to the surface of the substrate 9.

The dimension D2 corresponds to the maximum dimension (e.g., a dimension on the MTJ element side) of the contact plug 71. The dimension D1 corresponds to the maximum dimension (e.g., the dimension on the MTJ element side) of the contact plug 71. Regarding the dimension of each of the contact plugs 70 and 71, if the contact plug has a trapezoidal cross-section shape, a dimension of an upper portion side (the MTJ element side) of the contact plug is larger than a dimension of a lower portion side (the substrate side) of the contact plug.

For example, a central axis of the contact plug 71 along a direction perpendicular to the surface of the substrate 9 is shifted in the direction parallel (e.g., the Y direction) to the substrate surface from a central axis of the MTJ element 400 along the direction perpendicular to the surface of the substrate 9. In addition, the central axis of the contact plug 71 along the direction perpendicular to the surface of the substrate 9 is shifted in the direction parallel (e.g., the Y direction) to the substrate surface from the central axis of the contact plug 70 along the direction perpendicular to the surface of the substrate 9. However, the central axis of the contact plug 71 may be aligned with at least one of the central axis of the MTJ element 400 and the central axis of the contact plug 70.

A conductive layer 72 is provided between the contact plug (Cu-including layer) 71 and the lower electrode 40 of the MTJ element 400. The conductive layer 72 includes tantalum. A film thickness (a dimension in the direction perpendicular to the surface of the substrate 9) of the conductive layer 72 has a dimension of 2 nm or more and 5 nm or less. The film thickness of the conductive layer 72 may be adjusted as appropriate according to the dimension of the MTJ element 400.

For example, the conductive layer 72 is a tantalum layer in an amorphous state. However, the tantalum layer 72 may be a crystal layer. The conductive layer 72 may be a conductor (hereinafter, also referred to as a Ta-including layer) including tantalum. Thus, the conductive layer 72 may include elements other than tantalum (e.g., silicon and/or germanium, etc.). However, a ratio (composition ratio) of tantalum related to a plurality of elements included in the conductive layer 72 is preferably a half or more of the whole compositions of a plurality of elements forming the conductive layer 72.

The conductive layer 72 may be regarded as a part of a contact plug. In this case, the contact plug has a stacked structure of the Cu-including layer 71 and the Ta-including layer 72.

In this way, in the memory cell of the magnetic memory (e.g., MRAM) of the present embodiment, a plurality of contact plugs 70 and 71 couple the magnetoresistive effect element (e.g., the MTJ element) 400 to the cell transistor 600. The second contact plug (plug, portion) 71 is stacked onto the first contact plug 70 in the direction perpendicular to the surface of the substrate 9. The second contact plug 71 includes copper.

In the present embodiment, the magnetoresistive effect element 400 is provided on a position superposed on the contact plug 71 including Cu in the direction perpendicular to the surface of the substrate 9. The conductive layer 72 is provided between the magnetoresistive effect element 400 and the contact plug 71. The conductive layer 72 includes tantalum.

Thereby, the properties of the magnetoresistive effect element and the magnetic memory are improved in the magnetic memory of the present embodiment.

In the present embodiment, the operation of the MRAM that includes the magnetoresistive effect element 400 can suitably adopt well-known data write operations (e.g., data writing using a magnetic field writing system and/or Spin Torque Transfer (STT system), etc.) and well-known data read operations (e.g., data reading using a DC system, a reference cell system, and/or self-reference system, etc.). Therefore, in the present embodiment, a description of the operation of the MRAM that includes the MTJ element 400 of the present embodiment is omitted.

### (b) Manufacturing Method

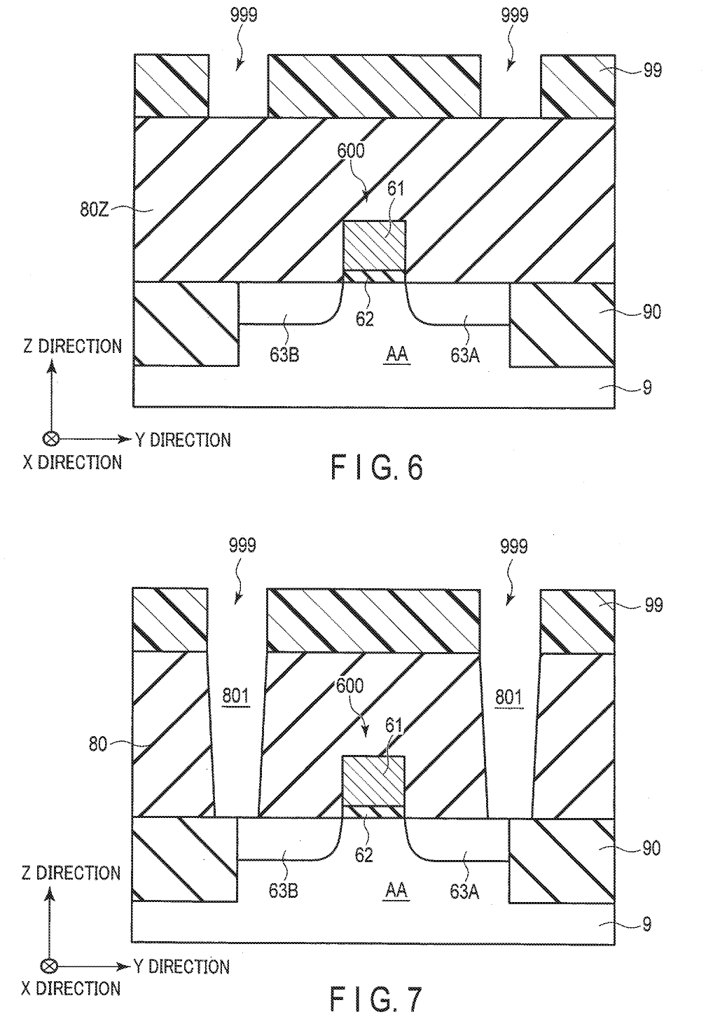

A method of manufacturing the magnetic memory of the present embodiment will be described with reference to FIGS. 6 to 17. In the description below, FIGS. 3 to 5 will also be referred to as appropriate.

FIGS. 6 to 17 are process cross-sectional diagrams illustrating each step of the method of manufacturing the magnetoresistive effect element (MTJ element) according to the present embodiment.

As illustrated in FIG. 6, the cell transistor (field-effect transistor) 600 is formed on the active area AA of the semiconductor substrate 9 by a well-known semiconductor process.

An insulator layer (interlayer insulator film) 80Z is formed on the substrate 9 so as to cover the cell transistor 600 by a film formation technique, such as CVD (chemical vapor deposition). The insulator layer 80Z is, for example, a silicon oxide (SiO₂) layer.

A mask layer (e.g., resist mask) 99 having a predetermined pattern 999 is formed on the insulator layer 80Z. The pattern 999 of the mask layer 99 is formed by the well-known lithography technique and etching technique. For example, the mask layer 99 has an opening pattern 999 having a circular planar shape. The opening pattern 999 is formed in a region where a contact plug is formed.

As illustrated in FIG. 7, an etching of the insulator layer is performed by, for example, RIE (reactive ion etching) based on the pattern 999 of the mask layer 99.

Thereby, a contact hole 801 is formed in the insulator layer 80. A part of the source/drain regions (diffusion layer) 63A and 63B of the cell transistor 600 exposes via the contact hole 801.

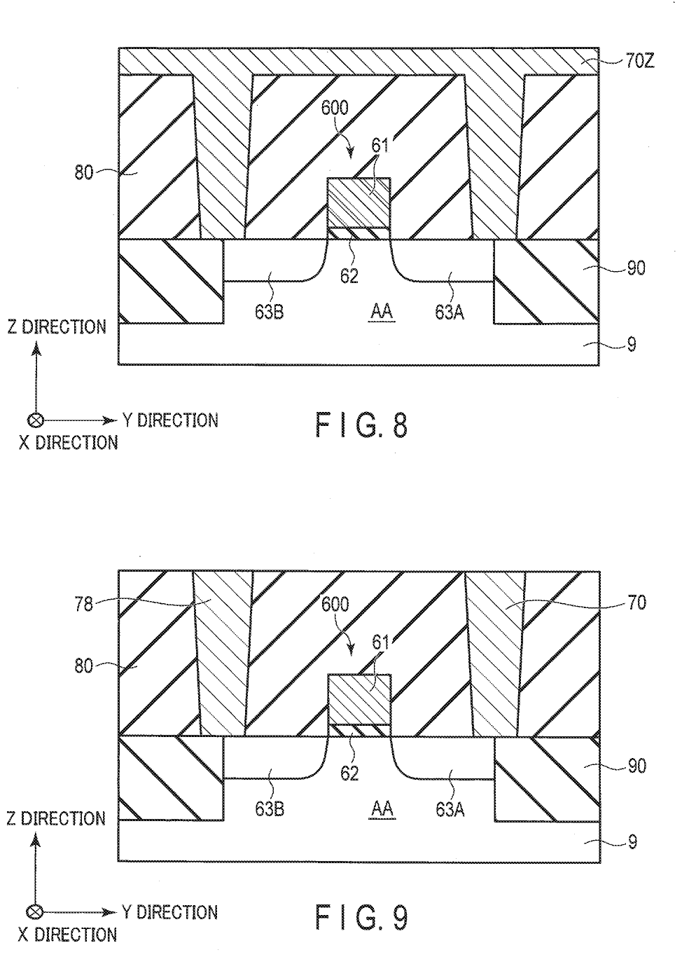

As illustrated in FIG. 8, after the mask layer is removed, a conductor 70Z is formed on the insulator layer 80 so as to fill the contact hole. The conductor 70Z includes, for example, at least one of titanium nitride (TiN) and tungsten (W). The conductor 70Z may be a stacked structure of titanium nitride and tungsten.

An upper face of the insulator layer 81 is used as a stopper to perform planarization processing such as the CMP (chemical mechanical polishing) method on the conductor 70Z. In this step, the upper face of the insulator layer 81 may be slightly abraded according to the conditions of the CMP.

Thereby, as illustrated in FIG. 9, the contact plugs 70 and 78 are formed in the interlayer insulator film 80. The contact plugs 70 and 78 contact the source/drain regions 63A and 63B of the cell transistor 600, respectively. The contact plugs 70 and 78 are formed by a damascene method. The contact plugs 70 and 78 having a damascene structure are formed in a contact hole (groove) in the interlayer insulator film 80 in a self-aligning manner.

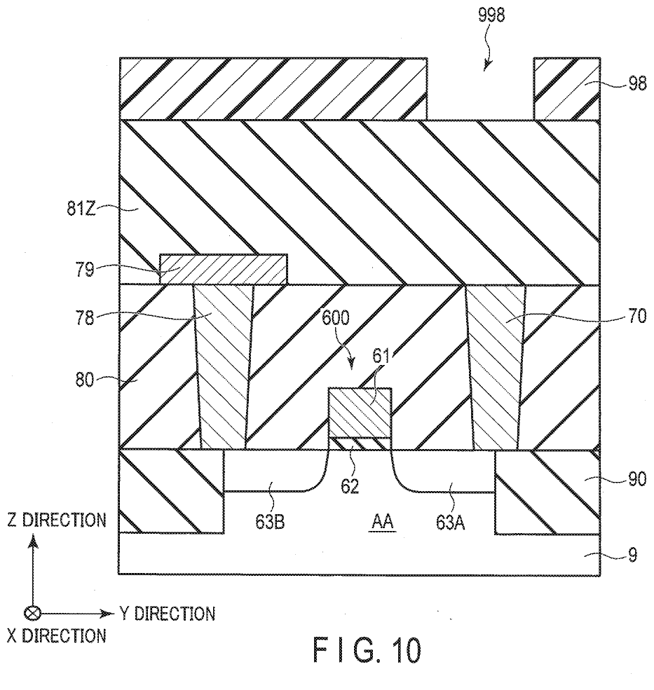

In the present embodiment, as illustrated in FIGS. 10 to 17 below, the contact plug (Cu-including layer) 71 including copper is formed above the contact plug 70 using a damascene method.

As illustrated in FIG. 10, after the source line bBL (conductive layer 79) is formed by the well-known interconnect formation process, an insulator layer 81Z is formed on the insulator layer 80 and the contact plug 70. The film thickness of the insulator layer 81Z is set as appropriate according to the dimension (height) of the contact plug and the dimension of the MTJ element to be formed in a subsequent step.

A mask layer 98 is formed on the insulator layer 81Z. The mask layer 98 has an opening pattern 998 on a position where a contact plug is to be formed. The opening pattern 998 is formed on a position partially superposed on the contact plug 70 in the direction perpendicular to the surface of the substrate 9.

Based on the pattern 998 of the mask layer 98, for example, an etching is performed on the insulator layer 81 by RIE.

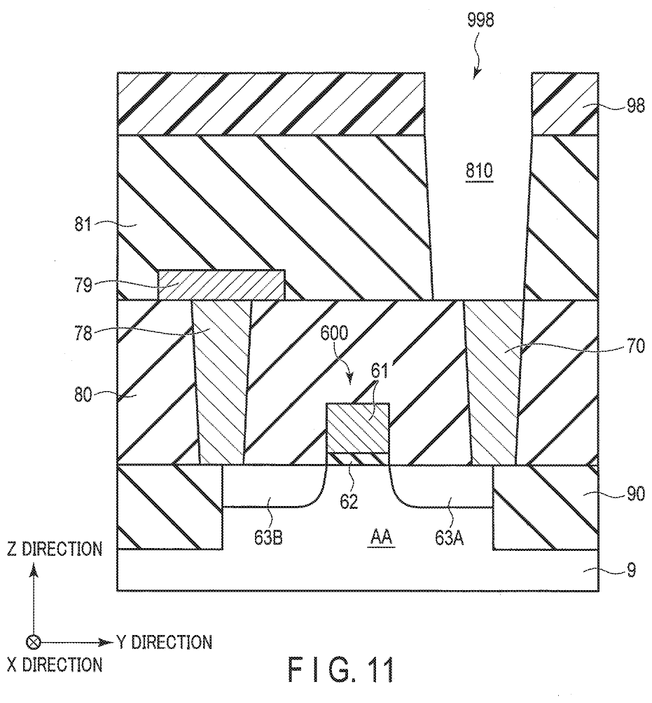

Thereby, as illustrated in FIG. 11, the contact hole 810 is formed in the insulator layer 81. By a sidewall of the insulator layer 81, an upper face of the contact plug 70, and an upper face of the interlayer insulator film 89 in the hole 810, a damascene groove 810 is formed in the insulator layer 81.

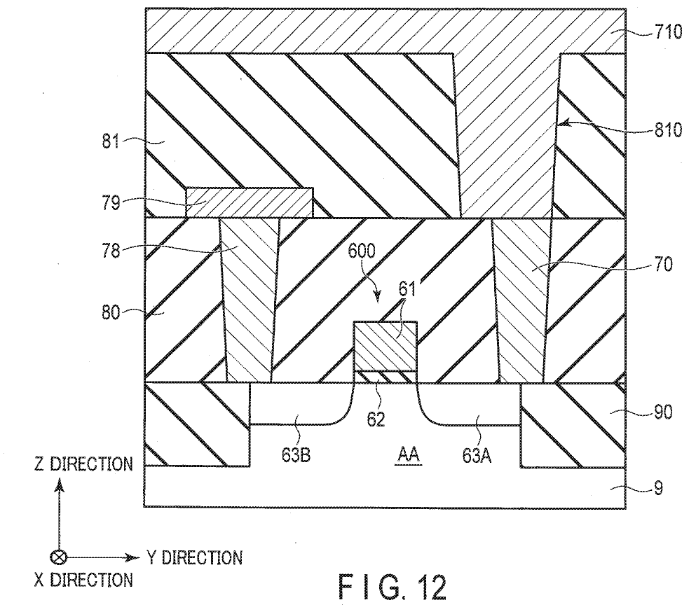

As illustrated in FIG. 12, a conductor 710 is formed on the insulator layer 81 and the contact plug 70 by, for example, the sputtering method so as to fill in the contact hole (damascene groove) 810. For example, the conductor 710 is a Cu layer or a conductive layer including Cu. For example, the conductive layer 710 including Cu is an alloy or compound including Cu as a main component.

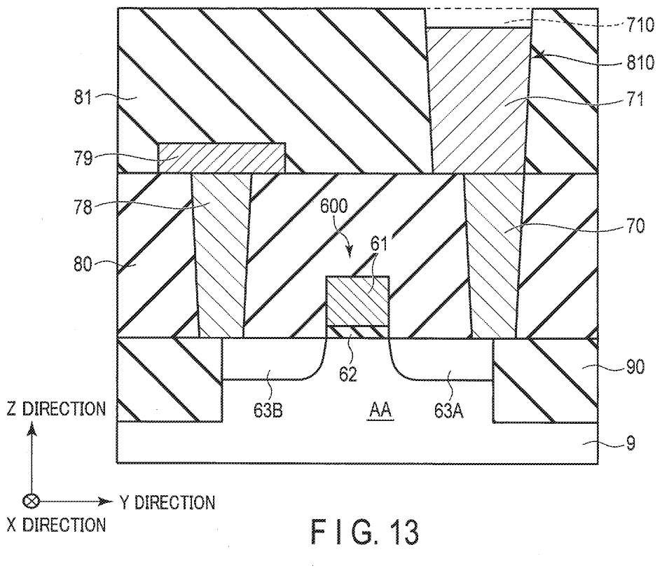

As illustrated in FIG. 13, planarization processing by the CMP method is performed on a conductor (Cu or a conductor including Cu) on the insulator layer 81. In planarization processing, an upper face of the insulator layer 81 may also be used as a stopper for the CMP on the conductor.

Thereby, the contact plug (Cu-including layer) 71 including Cu is formed in the contact hole (groove) 810 of the insulator layer 81 in a self-aligning manner.

For example, etch-back processing is performed on an upper face (an exposure face of the Cu-including layer) of the contact plug 71. The contact plug 71 is selectively etched. Thereby, a position of the upper face of the contact plug 71 recedes further toward the insulator layer 80 side (substrate 9 side) than a position of the upper face of the insulator layer 81. For example, the contact plug 71 is formed so as to have a film thickness (height) of 5 nm or more and 100 nm or less.

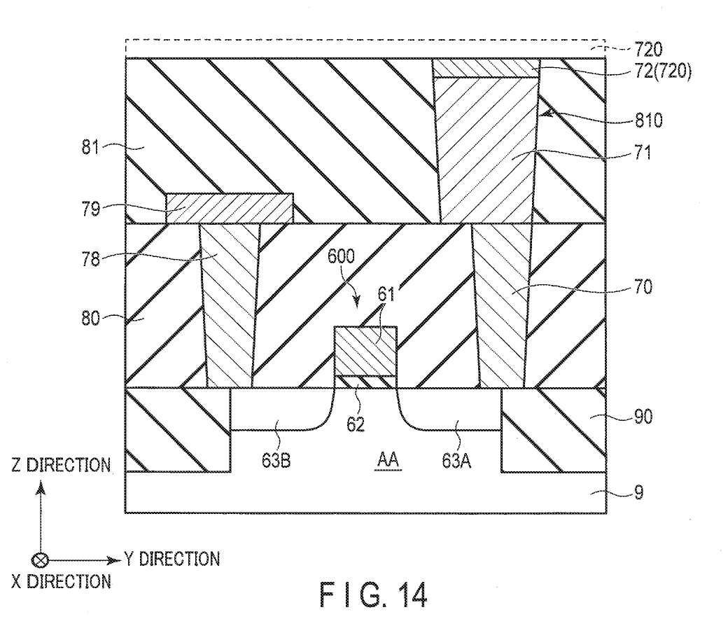

As illustrated in FIG. 14, a conductive layer (conductor) 720 is formed on the contact plug 70 and the insulator layer 81, for example, by the sputtering method. A material of the conductive layer 720 is, for example, tantalum (Ta) or a compound including tantalum.

For example, amorphous processing is performed on the tantalum layer (or a tantalum-including layer) 720. Thereby, the tantalum layer 72 comes to be in an amorphous state.

Amorphous processing of the tantalum layer 720 is performed by ion implantation. For example, at least one of silicon (Si) and germanium (Ge) is employed as the ion species of ion implantation. In this case, the tantalum layer 72 includes Si and/or Ge. Note that the ion species (e.g., argon) other than Si and Ge may be employed for ion implantation for making the conductive layer 720 into amorphous form. Note that amorphous processing is performed on the conductive layer 720 by a method other than ion implantation.

After that, planarization processing (or etch-back processing) by the CMP method is performed on the tantalum layer (Ta-including layer) 720. In planarization processing on the tantalum layer 720, the upper face of the insulator layer 81 is used as a stopper for CMP on the tantalum layer 720.

Thereby, the tantalum layer 72 is formed in the contact hole 810 of the insulator layer 81 in a self-aligning manner on the contact plug 71. For example, the tantalum layer 72 is formed so as to have a film thickness of 2 nm or more and 5 nm or less.

Note that amorphous processing may be performed on the conductive layer 720 after the CMP processing on the conductive layer 720. In addition, amorphous processing on the conductive layer 720 may be omitted.

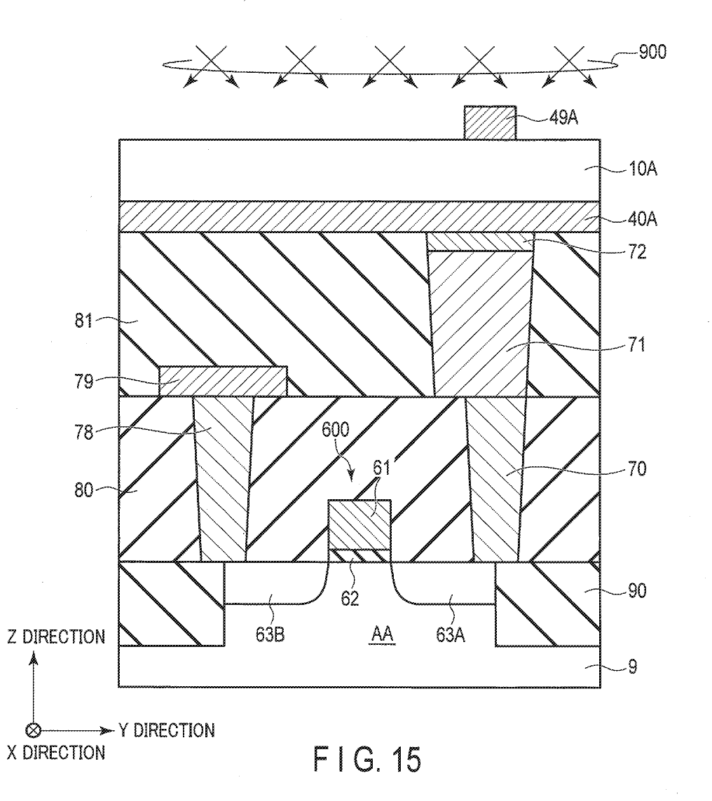

As illustrated in FIG. 15, a plurality of layers 40A, 10A, and 49A for forming the MTJ element are formed on the tantalum layer 53 and the insulator layer 81.

The conductive layer (lower electrode) 40A is formed on the tantalum layer 53. A stack 10A is formed on an upper face of the conductive layer 40A by, for example, the sputtering method.

The stack 10A includes, for example, an underlying layer, a first magnetic layer (e.g., a storage layer), a first non-magnetic layer (tunnel barrier layer), a second magnetic layer (e.g., a reference layer), a second non-magnetic layer (intermediate layer), and a third magnetic layer (e.g., shift canceling layer) in order from the substrate 9 side. Note that in the stack 10A, at least one of the underlying layer and the third magnetic layer need not be formed. In the case where the third magnetic layer is not formed, the second non-magnetic layer need not be formed.

A hard mask (e.g., conductive layer) 49A is formed on the stack 10A. For example, the hard mask 49A is disposed above the contact plug 71 in the direction perpendicular to the surface of the substrate 9.

The hard mask 49A has a predetermined pattern made by the lithography technique and the etching technique. The hard mask 49A is patterned based on the shape of an MTJ element to be formed. A material of the hard mask 49A is, for example, one or more selected from tungsten, tantalum, tantalum nitride, titanium, and titanium nitride.

The hard mask 49A is used as a mask to perform etching on a stack 10Z and an underlying layer 30Z.

For example, the stack 10A and the conductive layer 40A are processed into a shape corresponding to the hard mask 49A by ion beam etching. An ion beam 900 is radiated to the stack 10Z at an inclined angle with respect to the surface of the substrate 9 while rotating the substrate 9.

A type of etching performed on the stack 10A and the conductive layer 40A is not limited to ion beam etching.

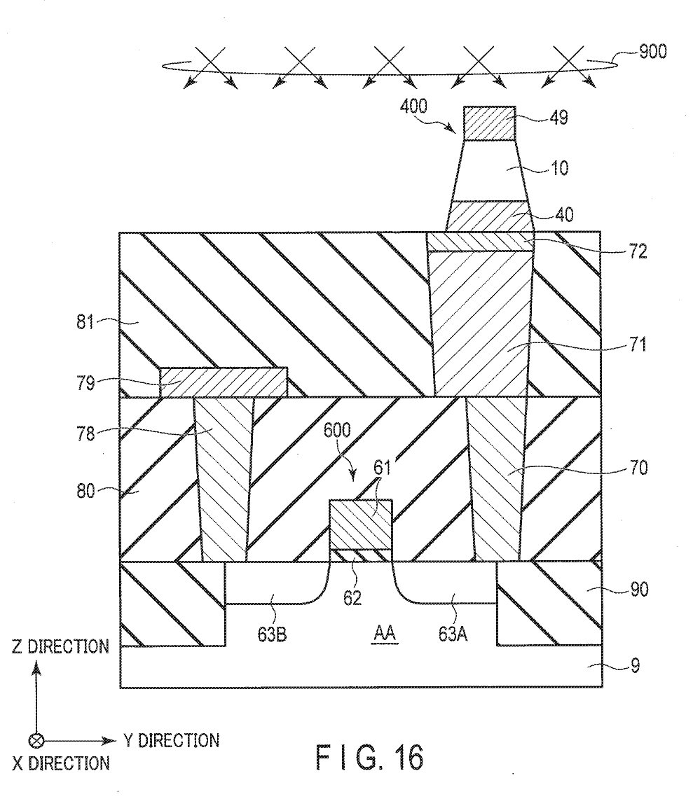

Thereby, the MTJ element 400 in the MRAM of the present embodiment is formed, as illustrated in FIG. 16. The hard mask is used as the upper electrode 49 of the MTJ element 400. The MTJ element 400 is formed on the conductive layer 72 on a position (immediately on the contact plug 71) superposed in the Z direction with respect to the contact plug 71 including Cu.

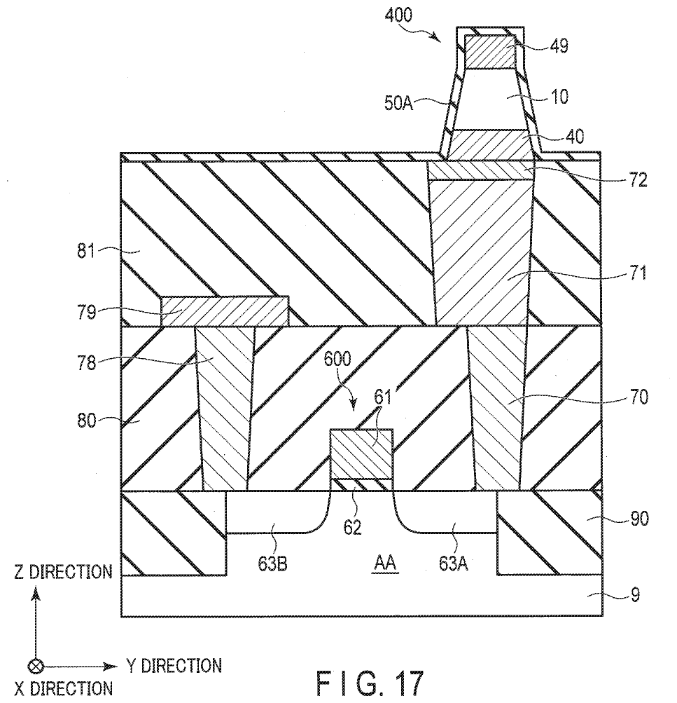

For example, an insulator film (protective film) 50A is formed so as to cover the MTJ element 400, as illustrated in FIG. 17. At least one of oxidation processing or nitriding processing may be performed before formation of the insulator film 50A, in order to isolate a substance attached to the lateral face of the MTJ element 400. An insulator film may be formed on the lateral face of the MTJ element 400 by isolating a substance attached to the lateral face of the MTJ element 400.

As illustrated in FIG. 5, an insulator layer 82 is formed on the insulator layers 50 and 80 and the MTJ element 400 so as to cover the MTJ element 400. A contact plug (bit line contact) 74 is formed in the insulator layer 82. A conductive layer 75 as the bit line BL is formed on the insulator layer 82 and the contact plug 74. Thereby, the bit line BL is coupled to the MTJ element 400 via the contact plug 74.

Through the above-described steps, the memory cell of the MRAM of the present embodiment is formed.

After that, a predetermined manufacturing step is performed, thereby ending the process of manufacturing the MTJ element of the present embodiment and the MRAM that includes the MTJ element of the present embodiment.

### (c) Conclusion

As described above, in the MRAM of the present embodiment, the contact plug (two contact plugs) having a stacked structure couples the magnetoresistive effect element to the cell transistor.

In the contact plug having a stacked structure between the magnetoresistive effect element and the cell transistor, the second contact plug 71 is stacked on the first contact plug 70 in the direction perpendicular to the surface of the substrate. The material of the second contact plug 71 is different from the material of the first contact plug 70.

Among the two stacked contact plugs, the second contact plug 71 on the magnetoresistive effect element 400 side is a conductor (e.g., Cu layer, Cu alloy, or conductive Cu compound) including copper (Cu). The contact plug 71 is formed by a damascene method. The contact plug 51 is the Cu-including layer 71 having a damascene structure.

The conductive layer 72 is provided between the Cu-including layer 51 having a damascene structure and the lower electrode 40 of the magnetoresistive effect element 400.

The Cu-including layer 51 having a damascene structure includes a relatively flat upper face. Each of the layers 11, 12, and 13 in the magnetoresistive effect element 400 can be formed on the relatively flat layer 51. Thus, a relatively flat/homogeneous magnetic layer and tunnel barrier layer can be formed. Accordingly, the properties of the magnetic layer and the tunnel barrier layer in the magnetoresistive effect element 400 are improved.

As a result, in the magnetic memory of the present embodiment, the properties of the magnetoresistive effect element (e.g., MR ratio, data retention property, etc.) are improved.

Cu has a relatively high heat conductivity. In the write operation and the read operation, there is a possibility that heat may be generated in the magnetoresistive effect element 400 due to a current flowing in the memory cell. In the present embodiment, heat generated in the magnetoresistive effect element 400 can be dissipated in a relatively efficient manner by the contact plug 71 including Cu.

Thus, the magnetic memory of the present embodiment can suppress an operation error (e.g., thermal disturbance) of the magnetoresistive effect element due to heat.

As a result, the operating properties of the memory can be improved in the magnetic memory of the present embodiment.

In addition, Cu has a relatively low electric resistance (resistivity). Thus, a current (electron and spin) can be supplied to the magnetoresistive effect element with relatively high efficiency. In addition, in the case where the material (e.g., a diamagnetic substance), such as Cu and Ta, and a magnetic substance (e.g., a ferromagnetic substance) are adjacent (joined), a relatively large spin-orbit interaction is generated, and a spin action can be supplied to the magnetoresistive effect element more efficiently.

Thus, like STT-MRAM for example, in a magnetic memory controlling magnetization alignment of a magnetoresistive effect element using a spin action, a material including Cu and/or Ta is used for a conductor coupled (supplying a current) to the magnetoresistive effect element so that spin torque can be applied to the magnetoresistive effect element (MTJ element) more efficiently.

Thereby, the properties of the magnetoresistive effect element as a memory element and the magnetic memory can be improved in the present embodiment.

Along with these, the reliability and manufacturing yield of the magnetic memory can be improved.

As described above, according to the magnetic memory of the present embodiment, the properties of the magnetic memory and the magnetic device (magnetoresistive effect element) can be improved.

### (2) MODIFICATIONS

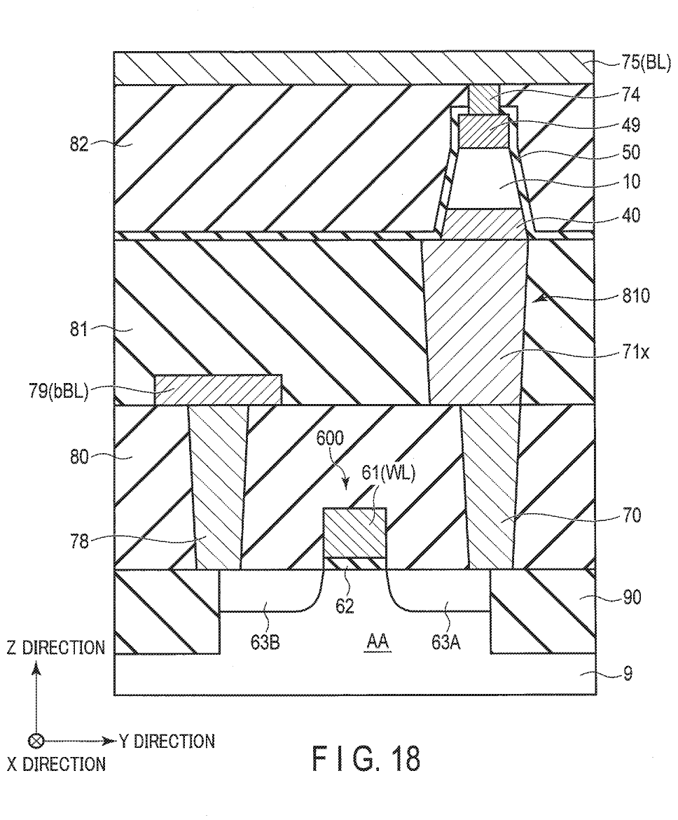

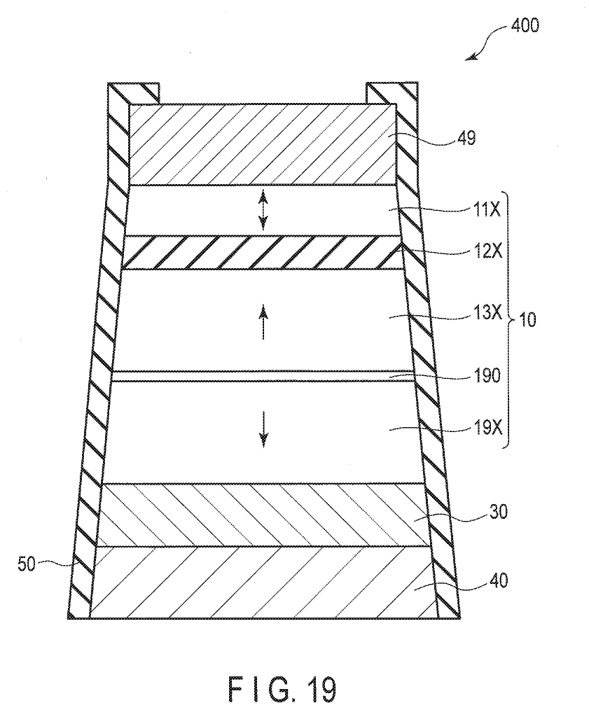

A modification of the magnetic memory of the embodiment will be described with reference to FIGS. 18 and 19.

### Modification 1

A modification 1 of the magnetic memory of the embodiment will be described with reference to FIG. 18.

FIG. 18 is a schematic cross-sectional diagram for explaining a magnetic memory (e.g., MRAM) of the modification 1.

As illustrated in FIG. 18, a conductive layer is not provided between the MTJ element 400 and a contact plug 71X including Cu.

In the present example, the lower electrode 40 of the MTJ element 400 directly contacts the contact plug (e.g., Cu layer) 71X including Cu. A film thickness of the contact plug 71X is substantially the same as a film thickness of the interlayer insulator film 81.

The MRAM of FIG. 18 can obtain the above-described effect by the contact plug (Cu-including layer) including Cu in the contact plug having a stacked structure.

Note that in the present modification, at least one of the magnetic layer (shift canceling layer) 19 and the underlying layer 30 need not be provided in the magnetoresistive effect element 400.

### Modification 2

A modification 2 of the magnetic device of the embodiment will be described with reference to FIG. 19.

FIG. 19 is a schematic cross-sectional diagram for explaining the magnetic device of the embodiment.

In an MTJ element 400X of the MRAM of the present embodiment, a storage layer 11X is provided on the upper electrode 49 side, and a reference layer 13X (and a shift canceling layer 19X) is provided on the lower electrode 40 side, as illustrated in FIG. 19.

In the MTJ element 400X of the modification 2, the reference layer 13X is located closer to the contact plug (Cu-including layer) 71 side than the storage layer 11X. The reference layer 13X is provided between the storage layer 11X and the conductive layer 72 (between a tunnel barrier layer 12X and the lower electrode 40). The storage layer 11X is provided between the tunnel barrier layer 12X and the upper electrode 49.

For example, a dimension of the reference layer 13X in the direction parallel to the surface of the substrate 9 is larger than a dimension of the storage layer 11X in the direction parallel to the surface of the substrate 9.

The MRAM of FIG. 19 achieves the above-described effect by the contact plug (Cu-including layer) including Cu in the contact plug having a stacked structure and the conductive layer 72.

In the present example as well, at least one of the magnetic layer (shift canceling layer) 19 and the underlying layer 30 need not be provided in the magnetoresistive effect element 400X.

### (3) OTHERS

The above-described embodiments show an example in which a field-effect transistor (a three-terminal type switching element) is provided as the selector (switching element) of the memory cell. The selector may be, for example, a two-terminal type switching element. If a voltage to be applied between two terminals is a threshold value or less, the switching element is in a “high-resistance” state, e.g., in an electrically non-conductive state. If a voltage to be applied between two terminals is a threshold value or more, the switching element is in a “low-resistance” state, e.g., in an electrically conductive state. The switching element may have this function even if the voltage has either polarity. This switching element includes at least one kind or more of chalcogen elements selected from a group consisting of Te, Se, and S. Alternatively, this switching element may include chalcogenide that is a compound including the above chalcogen element. This switching element may also include at least one kind or more of elements selected from a group consisting of B, Al, Ga, In, C, Si, Ge, Sn, As, P, and Sb.

Such a two-terminal type switching element is coupled to a magnetoresistive effect element via two contact plugs like the above-described embodiments. Among the two contact plugs, the contact plug on the magnetoresistive effect element side includes copper. A conductive layer (e.g., a layer including tantalum) is provided between the magnetoresistive effect element and the contact plug including copper.

The embodiment shows an example in which the magnetic memory of the present embodiment is MRAM. However, the magnetic memory of the present embodiment may be applied to magnetic memories other than MRAM. The magnetic memory of the present embodiment may also be applied to devices other than a memory device.

What is claimed is:

1. A magnetic memory comprising:
a semiconductor substrate;
a switching element above the semiconductor substrate, the switching element provided between a first terminal and a second terminal;
a first contact portion coupled to the first terminal and provided in a first insulator layer on the semiconductor substrate;
a second contact portion including copper and provided in a second insulator layer on the first insulator layer;
a conductive layer provided on the second contact portion; and
a magnetoresistive effect element provided on the conductive layer.

2. The magnetic memory according to claim 1, wherein the second insulator layer includes a first groove, and the second contact portion is provided in the first groove.

3. The magnetic memory according to claim 1, wherein the conductive layer includes tantalum.

4. The magnetic memory according to claim 1, wherein the conductive layer is an amorphous layer.

5. The magnetic memory according to claim 1, wherein the first contact portion includes at least one of titanium and tungsten.

6. The magnetic memory according to claim 1, wherein the magnetoresistive effect element is provided at a position superposed on the second contact portion in a direction perpendicular to a surface of the semiconductor substrate via the conductive layer.

7. The magnetic memory according to claim 1, wherein a film thickness of the conductive layer is smaller than a film thickness of the second contact portion.

8. The magnetic memory according to claim 1, wherein a film thickness of the second contact portion has a value in a range from 5 nm to 100 nm.

9. The magnetic memory according to claim 1, wherein a film thickness of the conductive layer has a value in a range from 2 nm to 5 nm.

10. The magnetic memory according to claim 1, wherein the second contact portion includes a first portion, and a second portion between the conductive layer and the first portion, and wherein a dimension of the second portion in a direction parallel to a surface of the substrate is larger than a dimension of the first portion in the direction parallel to the surface of the substrate.

11. The magnetic memory according to claim 1, wherein the second contact portion has a trapezoidal cross-section shape.

12. The magnetic memory according to claim 1, wherein a film thickness of the second contact portion is smaller than or equal to a film thickness of the first contact portion.

13. The magnetic memory according to claim 1, wherein the magnetoresistive effect element includes a first magnetic layer having magnetization in a variable state, a second magnetic layer having magnetization in a fixed state, and a non-magnetic layer between the first magnetic layer and the second magnetic layer.

14. A magnetic memory comprising:
a semiconductor substrate;
a switching element above the semiconductor substrate, the switching element provided between a first terminal and a second terminal;
a first contact portion coupled to the first terminal and provided in a first insulator layer on the semiconductor substrate;
a second contact portion including copper and provided in a second insulator layer on the first insulator layer; and
a magnetoresistive effect element provided on the second contact portion.

15. The magnetic memory according to claim 14, wherein the second insulator layer includes a first groove, and the second contact portion is provided in the first groove.

16. The magnetic memory according to claim 14, wherein the first contact portion includes at least one of titanium and tungsten.

17. The magnetic memory according to claim 14, wherein the magnetoresistive effect element is provided at a position superposed on the second contact portion in a direction perpendicular to a surface of the semiconductor substrate.

18. The magnetic memory according to claim 14, wherein a film thickness of the second contact portion has a value in a range from 5 nm to 100 nm.

19. The magnetic memory according to claim 14, wherein the second contact portion includes a first portion, and a second portion between the magnetoresistive effect element and the first portion, and wherein a dimension of the second portion in a direction parallel to a surface of the substrate is larger than a dimension of the first portion in the direction parallel to the surface of the substrate.

20. The magnetic memory according to claim 14, wherein the second contact portion has a trapezoidal cross-section shape.
